(19) United States
(12) Patent Application Publication
(10) Pub. No.: US 2012/0260857 A1
(43) Pub. Date: Oct. 18, 2012

(54) HEAT TREATMENT APPARATUS

(75) Inventors: Kiyohiko TAKAHASHI, Iwate (JP); Hirofumi Kaneko, Iwate (JP)

(73) Assignee: Tokyo Electron Limited, Tokyo (JP)

(21) Appl. No.: 13/448,512

(22) Filed: Apr. 17, 2012

(30) Foreign Application Priority Data
Apr. 18, 2011 (JP) 2011-092188

(51) Int. Cl. C23C 16/46

(52) U.S. Cl. 118/725

(57) ABSTRACT

A heat treatment apparatus includes a reaction tube extending in a first direction; a substrate support unit which is placed in the reaction tube and is configured to be capable of supporting plural substrates along the first direction; plural gas supply pipes provided at a side surface of the reaction tube to be aligned in the first direction with intervals for supplying a gas into the reaction tube; a gas dispersing plate which is provided in the reaction tube between opening edges of the plural gas supply pipes and the substrate support unit placed in the reaction tube, the gas dispersing plate being provided with plural opening portions formed to correspond to the gas supply pipes, respectively; and a heater which is placed outside the reaction tube for heating the substrates.

### BACKGROUND OF THE INVENTION

1. Field of the Invention

The present invention relates to a heat treatment apparatus and more specifically, to a heat treatment apparatus that performs heat treatment on plural substrates.

2. Description of the Related Art

In a method of manufacturing a semiconductor device, there exists a heat treatment apparatus of a batch type in which plural substrates are placed at a predetermined interval, and are performed with heat treatment at the same time. This type of heat treatment apparatus includes a reaction tube provided with an opening at the lower end, a substrate support unit capable of being placed in the reaction tube and supporting plural substrates at a predetermined interval, and a heater provided outside of the reaction tube for heating the substrates in the reaction tube. Further, a gas supply nozzle for supplying a process gas is provided in the reaction tube that extends from the opening at the lower end to upward along the substrate support unit.

The substrates are performed in accordance with the kind of the process gas by introducing the substrate support unit supporting the substrates in the reaction tube, and flowing the process gas from the gas supply nozzle while heating the substrates by the heater.

### PATENT DOCUMENT

[Patent Document 1] Japanese Laid-open Patent Publication No. 2000-068214
[Patent Document 2] Japanese Laid-open Patent Publication No. 2008-172205

In the above described heat treatment apparatus, if the gas supply nozzle extends higher than the upper end of the substrate support unit and the process gas is supplied from the upper end of the gas supply nozzle, there is a risk that the process gas is in shortage near the lower end of the substrate support unit. In such a case, the substrates near the upper end of the substrate support unit and the substrates near the lower end of the substrate support unit may be affected differently, so that uniformity of the process may be reduced. Thus, a heat treatment apparatus in which plural gas supply nozzles having different lengths, or a gas supply nozzle in which plural holes at a predetermined interval are provided, has been developed. This type of apparatus is aimed at supplying the process gas from plural positions in the longitudinal direction of the substrate support unit to improve the uniformity of the process (Patent Document 1, for example).

However, in this case, as the process gas is heated while flowing through the gas supply nozzle from downward to upward, the process gas with a higher temperature is supplied from the hole near the upper end of the gas supply nozzle compared with the hole near the lower end. Therefore, the uniformity of the process is not significantly improved.

Further, when two kinds of source gases are used as the process gas where the decomposition temperature of one of the source gasses is extremely lower than that of the other of the source gasses, the source gas whose decomposition temperature is lower may start to decompose, especially near the upper end of the gas supply nozzle. In this case, a layer is formed inside the gas supply nozzle or in the reaction tube, so that the rate of forming the layer on the substrates becomes slower. Further, the source gas cannot be efficiently used. Yet further, the layer formed in the reaction tube becomes particles when peeled, which contaminates the apparatus. In such a case, it is necessary to increase cleaning time of the reaction tube which in turn lowers the throughput.

Thus, a technique by which a gas supply pipe, sectioned into plural areas in the vertical direction, is provided at the side of the reaction tube for supplying the source gas from the side (Patent Document 2, for example). However, even when the gas supply pipe is sectioned into the plural areas, it is still difficult to provide the source gas uniformly to the plural substrates.

### SUMMARY OF THE INVENTION

The present invention is made in light of the above problems, and provides a heat treatment apparatus in which plural substrates are placed at a predetermined interval, capable of improving the uniformity of the process for the plural substrates.

According to an embodiment, there is provided a heat treatment apparatus including a reaction tube extending in a first direction; a substrate support unit which is placed in the reaction tube and is configured to be capable of supporting plural substrates along the first direction; plural gas supply pipes provided at a side surface of the reaction tube to be aligned in the first direction with intervals for supplying a gas into the reaction tube; a gas dispersing plate which is provided in the reaction tube between opening edges of the plural gas supply pipes and the substrate support unit placed in the reaction tube, the gas dispersing plate being provided with plural opening portions formed to correspond to the gas supply pipes, respectively; and a heater which is placed outside the reaction tube for heating the substrates.

According to the embodiment, a heat treatment apparatus in which plural substrates are placed at a predetermined interval, capable of improving the uniformity of the process for the plural substrates is provided.

### BRIEF DESCRIPTION OF THE DRAWINGS

Other objects, features and advantages of the present invention will become more apparent from the following detailed description when read in conjunction with the accompanying drawings.

FIG. 1 is a cross-sectional view showing an example of a heat treatment apparatus of an embodiment;

FIG. 2 is a perspective view of an example of an inner tube of an embodiment;

FIG. 3A is a top cross-sectional view of an example of the inner tube of an embodiment;

FIG. 3B is a side view showing an example of the structure of a gas dispersing plate of an embodiment;

FIG. 4 is a perspective view showing an example of the structures of a first heater of a heater and an outer tube of an embodiment;

FIG. 5A, FIG. 5B and FIG. 5C are perspective views of an example of an attaching tool and a fixing ring;

FIG. 6 is a partial perspective view of the upper portion of an outer tube;

FIG. 7A to FIG. 7D are cross-sectional views showing the lower parts of the inner tube and the outer tube;

FIG. 8A to FIG. 8D are diagrams showing computer simulation results of a gas supplied to the inner tube from a gas supply pipe through a gas supply hole;

FIG. 9A to FIG. 9D are views showing other examples of the gas dispersing plate of an embodiment;

FIG. 10 is a view showing an example of a system in which a gas supply system is connected to the heat treatment apparatus of an embodiment;

FIG. 11A is a cross-sectional view showing another example of the heat treatment apparatus of an embodiment; and

FIG. 11B is a top cross-sectional view of another example of the inner tube of an embodiment.

### DETAILED DESCRIPTION OF THE PREFERRED EMBODIMENTS

The invention will be described herein with reference to illustrative embodiments. Those skilled in the art will recognize that many alternative embodiments can be accomplished using the teachings of the present invention and that the invention is not limited to the embodiments illustrated for explanatory purposes.

It is to be noted that, in the explanation of the drawings, the same components are given the same reference numerals, and explanations are not repeated.

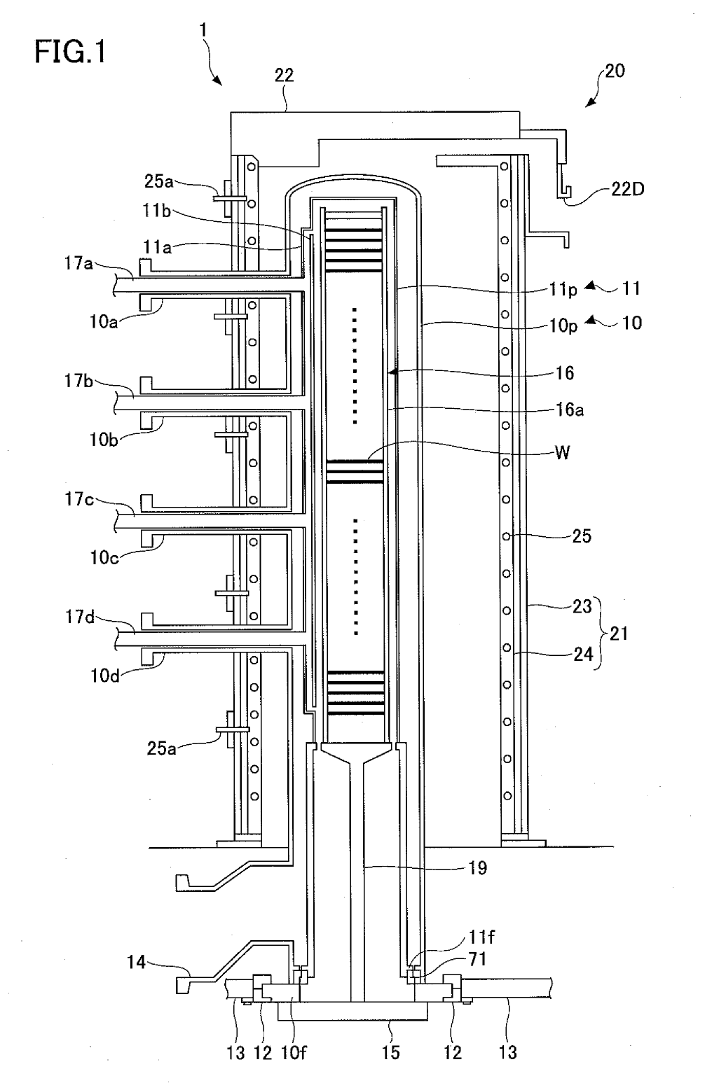

FIG. 1 is a cross-sectional view showing an example of a heat treatment apparatus 1 of the embodiment.

The heat treatment apparatus 1 is a batch type in which plural substrates are placed at a predetermined interval, and heat treatment is performed at the same time.

The heat treatment apparatus 1 of the embodiment includes an outer tube 10 (reaction tube), an inner tube 11, a substrate support unit 16, a heater 20, a gas dispersing plate 11b, a support plate 12, a base plate 13, an exhaust pipe 14, a cover member 15, gas supply pipes 17a to 17d, a support rod 19, and a fixing ring 71 (ring member).

The outer tube 10 includes a cylindrical tube portion 10p whose lower part is opened and the upper part is sealed, plural (e.g. four in FIG. 1, although other amounts could be used) guide pipes 10a, 10b, 10c and 10d provided at a side surface of the tube portion 10p, and a flange 10f provided at the lower end (lower opening portion) of the tube portion 10p. The guide pipes 10a to 10d are provided at the side surface of the cylindrical tube portion 10p to be substantially aligned in a line along the longitudinal direction (first direction, vertical direction in FIG. 1) of the tube portion 10p at a predetermined interval.

The outer tube 10 may be, for example, made of quartz glass. The outer tube 10 may be, for example, formed as follows. First, the tube portion 10p, which is a cylindrical tube with a cover, is provided with plural holes at a predetermined interval at the side surface of the tube portion 10p along the longitudinal direction of the tube portion 10p. Then, plural pipes are attached to the tube portion 10p by welding or the like such that the front edges of the plural pipes are connected to the plural holes, respectively. These pipes become the guide pipes 10a to 10d.

Further, the flange 10f is provided at the lower end of the outer tube 10. The flange 10f is supported by the support plate 12 via a predetermined seal member (not shown in the drawings). The support plate 12 is bolted to the base plate 13 so that the outer tube 10 is fixed to the base plate 13.

The inner tube 11 includes a cylindrical tube portion 11p whose lower part is opened and the upper part is sealed, a protruding portion 11a provided at the side surface of the tube portion 11p, and a flange 11f provided at the lower end (hereinafter simply referred to as lower opening portion as well) of the tube portion 11p. The inner tube 11 is capable of being inserted into the outer tube 10 from the lower opening portion of the outer tube 10 and being pulled out from the outer tube 10 from the lower opening portion of the outer tube 10.

The inner tube 11 is supported by the outer tube 10 via the fixing ring 71. It means that the flange 11f of the inner tube 11 is supported by the fixing ring 71 and the fixing ring 11 is supported by the outer tube 10 so that the inner tube 11 is fixed to the outer tube 10. The structure of the inner tube 11 and a method of attaching the inner tube 11 to the outer tube 10 will be explained later in detail.

The gas supply pipes 17a to 17d are provided at the side surface of the cylindrical tube portion 11p of the inner tube 11 to be substantially aligned in a line along the longitudinal direction (vertical direction in FIG. 1) of the tube portion 11p at a predetermined interval.

The guide pipes 10a to 10d of the outer tube 10 are provided to correspond with the gas supply pipes 17a to 17d, respectively. The gas supply pipes 17a to 17d are inserted into the corresponding guide pipes 10a to 10d. In other words, the gas supply pipes 17a to 17d are supported by the corresponding guide pipes 10a to 10d, respectively. Pipes of a gas supply system are connected to the gas supply pipes 17a to 17d, and process gasses from the gas supply system are supplied into the inner tube 11 via the gas supply pipes 17a to 17d (which will be explained later).

The substrate support unit 16 supports plural wafers W (substrate) at a predetermined interval in the vertical direction in FIG. 1. The substrate support unit 16 is capable of being inserted into the inner tube 11 from the lower opening portion of the inner tube 11 and being pulled out from the inner tube 11 from the lower opening portion of the inner tube 11.

The substrate support unit 16 includes at least three poles 16a. Each of the poles 16a is provided with plural notch portions at a predetermined interval, and the wafers W are supported by the substrate support unit 16 by having peripheral portions inserted into the notch portions, respectively. In this embodiment, for example, the substrate support unit 16 may support 117 wafers W. Specifically, the substrate support unit 16 may support four dummy wafers from the upper side, four dummy wafers from the lower side, and four sets of 25 process wafers W which are separated by three dummy wafers respectively. Further, the substrate support unit 16 may be placed such that among the 100 process wafers W, the process gas from the gas supply pipe 17a is substantially supplied to the upper 25 process wafers W, the process gas from the gas supply pipe 17b is substantially supplied to the next upper 25 process wafers W, the process gas from the gas supply pipe 17c is substantially supplied to the next 25 process wafers W, and the process gas from the gas supply pipe 17d is substantially supplied to the lower 25 process wafers W.

The substrate support unit 16 is fixed on the support rod 19. The support rod 19 is supported by the cover member 15. The cover member 15 is raised and lowered by a lifting mechanism (not shown in the drawings). With this, the support rod 19 and the substrate support unit 16 are capable of being inserted into and pulled out from the inner tube 11. When the substrate support unit 16 is inserted into the inner tube 11, the cover member 15 touches the lower surface of the flange 10f of the outer tube 10 via a seal member (not shown in the drawings) so that the inside of the outer tube 10 is isolated from the outside atmosphere.

Alternatively, an opening through which the support rod 19 is capable of being inserted may be provided to the cover member 15, the support rod 19 may be inserted through the opening, a space between the opening and the support rod 19 may be sealed by a magnetic fluid or the like, and the support rod 19 may be rotated by a rotating mechanism (not shown in the drawings). With this structure, the substrate support unit 16 and the wafers W are also rotated so that the gas supplied from the gas supply pipes 17a to 17d may be more homogeneously applied to the wafers W.

The heater 20 is provided to surround the outer tube 10. The heater 20 heats the wafers W supported by the substrate support unit 16 via the outer tube 10 and the inner tube 11. The heater 20 includes a first heater 21 that covers the side surface of the outer tube 10 and a second heater 22 that covers the upper edge of the first heater 21.

The first heater 21 includes a metal tubular body 23, an insulating body 24 which is provided along inside surface of the tubular body 23, and a heater element 25 which is supported by the insulating body 24. The heater 20 is further provided with an upper exhaust port 22D at the upper end of the first heater 21 for exhausting air (which will be explained later) supplied into the inner space between the heater 20 and the outer tube 10. The air is exhausted from the inner space of the heater 20 via an exhaust pipe (not shown in the drawings) connected to the upper exhaust port 22D. Further, current supply terminals 25a for supplying electric power to the heater elements 25 are provided at the side surface of the tubular body 23 of the first heater 21. The heater 20 will be explained later in detail.

The exhaust pipe 14 is provided at the lower part of the tube portion 10p of the outer tube 10. The exhaust pipe 14 is provided below the guide pipe 10d which is at the lowest position among the plural guide pipes 10a to 10d. A flange is formed at an edge of the exhaust pipe 14 to be connected to an exhaust system (which will be explained later) via a predetermined connecting part.

With this structure, the process gas supplied into the inner tube 11 via the gas supply pipes 17a to 17d is exhausted from the exhaust pipe 14 after passing through surfaces of the wafers W via one or more openings or slits (not shown in the drawings) provided to the inner tube 11.

Next, the structure of the inner tube 11 of the embodiment is explained.

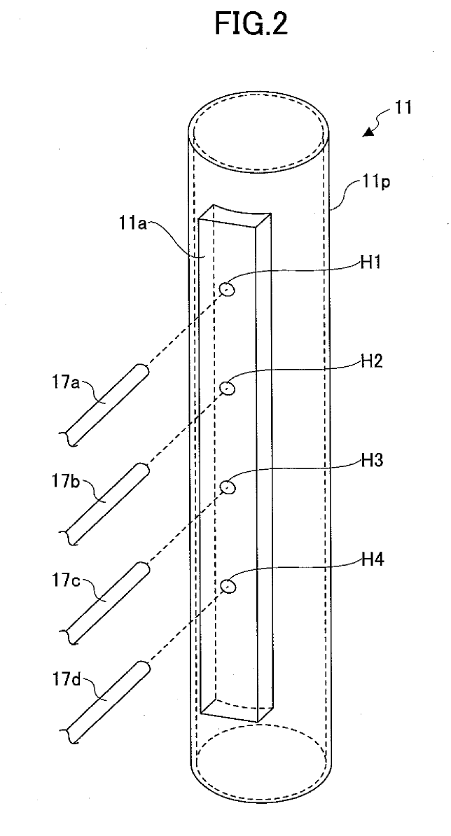

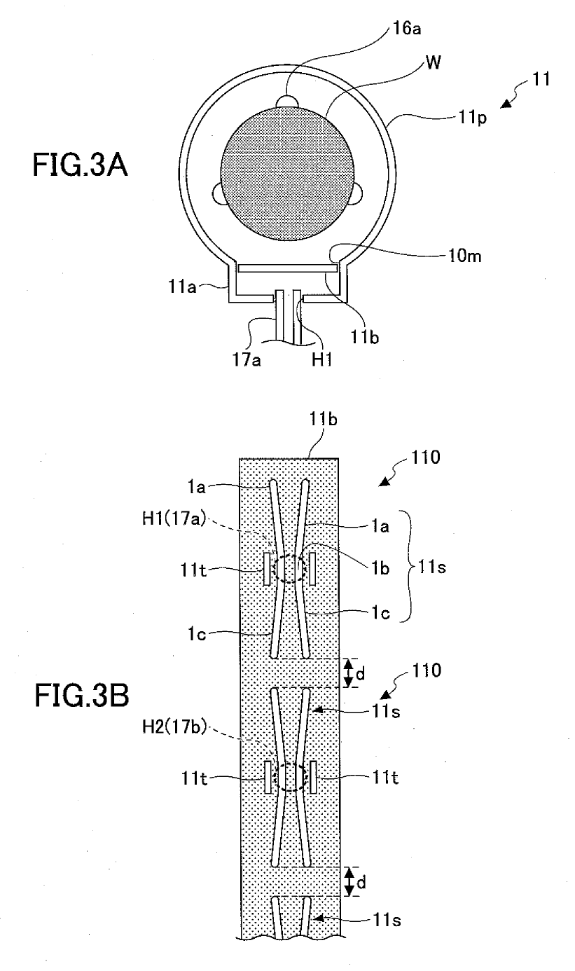

FIG. 2 is a perspective view of the inner tube 11 of the embodiment. FIG. 3A is a top cross-sectional view of the inner tube 11 of the embodiment.

The inner tube 11 may be, for example, made of quartz glass. The tube portion 11p of the inner tube 11 is provided with a rectangular opening extending in the longitudinal direction at the side surface of the tube portion 11p. The protruding portion 11a has a rectangular box shape corresponding to the opening to be attached to the tube portion 11p to cover the opening. In this embodiment, the protruding portion 11a is provided to protrude from the side surface of the tube portion 11p.

The protruding portion 11a is provided with plural gas supply holes H1 to H4 to be substantially aligned in a line along the longitudinal direction of the inner tube 11 at a predetermined interval. As shown in FIG. 2, the gas supply holes H1 to H4 are provided to correspond to the gas supply pipes 17a to 17d. In other words, the gas supply pipes 17a to 17d are supported by the guide pipes 10a to 10d of the outer tube 10 (see FIG. 1) so that the opening edges of the gas supply pipes 17a to 17d come close to the corresponding gas supply holes H1 to H4, respectively (although the gas supply pipes 17a to 17d and the corresponding gas supply holes H1 to H4 are separated for explanation in FIG. 2). With this structure, the process gas from the gas supply system is supplied into the inner tube 11 via the gas supply pipes 17a to 17d and the gas supply holes H1 to H4.

As shown in FIG. 3A, the inner diameter of the gas supply hole H1 may be formed a bit larger than the outer diameter of the gas supply pipe 17a. With this, the gas supply pipe 17a is capable of being inserted into the protruding portion 11a through the gas supply hole H1. However, the structure is not limited and the inner diameter of the gas supply hole H1 and the inner diameter of the gas supply pipe H1 may be equal, for example.

Referring to FIG. 3A, the gas dispersing plate 11b is provided at an interface between the protruding portion 11a and the inner tube 11 to cover or block an opening 10m of the protruding portion 11a.

FIG. 3B is a side view showing an example of the structure of the gas dispersing plate 11b.

The gas dispersing plate 11b is provided with plural slit assemblies 110. Each of the slit assemblies 110 is provided to correspond with each of the gas supply pipes 17a to 17d, in other words, each of the gas supply holes H1 to H4 of the protruding portion 11a. In this embodiment, the gas dispersing plate 11b is provided with the four slit assemblies 110 corresponding to the gas supply holes H1 to H4 of the protruding portion 11a, respectively. In FIG. 3B, positions corresponding to the opening edges of the gas supply pipes 17a and 17b are shown by dotted lines for explanation.

In this embodiment, each of the slit assemblies 110 includes two slit portions 11s and two slits 11t. Each of the slit portions 11s is provided with a first slit 1a, a second slit 1b which is connected to the lower edge of the first slit 1a and a third slit 1c which is connected to the lower edge of the second slit 1b. The first slit 1a is extending to be inclined with respect to the longitudinal direction of the gas dispersing plate 11b (longitudinal direction of the inner tube 11). The second slit 1b is extending in the longitudinal direction of the gas dispersing plate 11b. The third slit 1c is extending to be inclined with respect to the longitudinal direction of the gas dispersing plate 11b opposite to the first slit 1a. Here, the opening edges of the gas supply pipes 17a to 17d are positioned to substantially face the corresponding second slits 1b of the two slit portions 11s, respectively.

Here, each of the slit portions 11s is provided to extend along the longitudinal direction of the gas dispersing plate 11b. In this embodiment, the plural slit assemblies 110 are provided along the longitudinal direction of the gas dispersing plate 11b such that the slit portions 11s are positioned uniformly along an entire length of the gas dispersing plate 11b along the longitudinal direction.

The two slit portions 11s of each of the slit assemblies 110 are positioned to have a predetermined distance between the two slit portions 11s in a width direction (second direction) perpendicular to the longitudinal direction of the gas dispersing plate 11b while having a position (shown as the dotted lines) corresponding to the respective gas supply pipe (17a or the like) as a center. Further, the two slit portions 11s of each of the slit assemblies 110 are formed such that while having the position (shown as the dotted lines) corresponding to the respective gas supply pipe (17a or the like) as a center, the further the distance from the position along the longitudinal direction of the dispersing plate 11b, the greater the distance becomes between the slit portions 11s in the width direction. In other words, the two slit portions 11s of each of the slit assemblies 110 are provided, while having the position (shown as the dotted lines) corresponding to the respective gas supply pipe (17a or the like) as a center, to extend in the upper and lower direction and expand in the rightward and leftward (width direction) in FIG. 3B. The two slit portions 11s of each of the slit assemblies 110 have a substantially “X” shape.

In other words, the first slits 1a or the second slits 1c, of the two slit portions 11s of each of the slit assemblies 110 are provided to be inclined in different directions from each other along the longitudinal direction of the gas dispersing plate 11b, respectively.

Further, the distance “d” between the two slit portions 11s of the adjacent slit assemblies 110 may be set such that the gas is uniformly supplied to the plural wafers W placed in the inner tube 11, although an appropriate distance depends on the condition of the slit assemblies 110 such as the length of each of the slit portions 11s or the like. For example, by setting the distance “d” within a predetermined length, sufficient gas is supplied to the wafer W which is placed corresponding to a position between the adjacent slit assemblies 110. Further, by setting the distance “d” more than a predetermined distance, it is possible to prevent an excess supply of the gas to the wafer W which is placed corresponding to the position between the adjacent slit assemblies 110 because of overlapping of the gas from both of the slit assemblies 110. With this structure, the gas supplied from the gas supply pipes 17a to 17d can be uniformly provided to the plural wafers W placed in the inner tube 11.

In each of the slit assemblies 110, the two slits 11t are provided at both sides of the corresponding two slit portions 11s to be substantially parallel with the second slits 1b. By providing the slits 11t as such, the gas can be further dispersed uniformly.

Further, each of the slit portions 11s may be formed to have a width in the width direction smaller than that of the opening edge of the corresponding gas supply pipe (17a or the like). With this structure, the gas flowing out from the gas supply pipe (17a or the like) is temporarily blocked by the gas dispersing plate 11b and is not directly supplied to the wafers W supported by the substrate support unit 16.

The gas dispersing plate 11b may be, for example, made of quartz glass. Further, as shown in FIG. 3A, the gas dispersing plate 11b is provided to have an interval from the opening edges of the gas supply pipes 17a to 17d. Thus, the gas flowing out from the opening edges of the gas supply pipes 17a to 17d flows along the gas dispersing plate 11b while being dispersed in the protruding portion 11a, and then is supplied to the wafers W supported by the substrate support unit 16 via the slit assemblies 110.

The shape or design of the slit assembly 110 (opening) provided to the gas dispersing plate 11b is not limited to the above example and may be varied in many ways. For example, for the structure shown in FIG. 3B, each of the slit assemblies 110 may not include the two slits 11t.

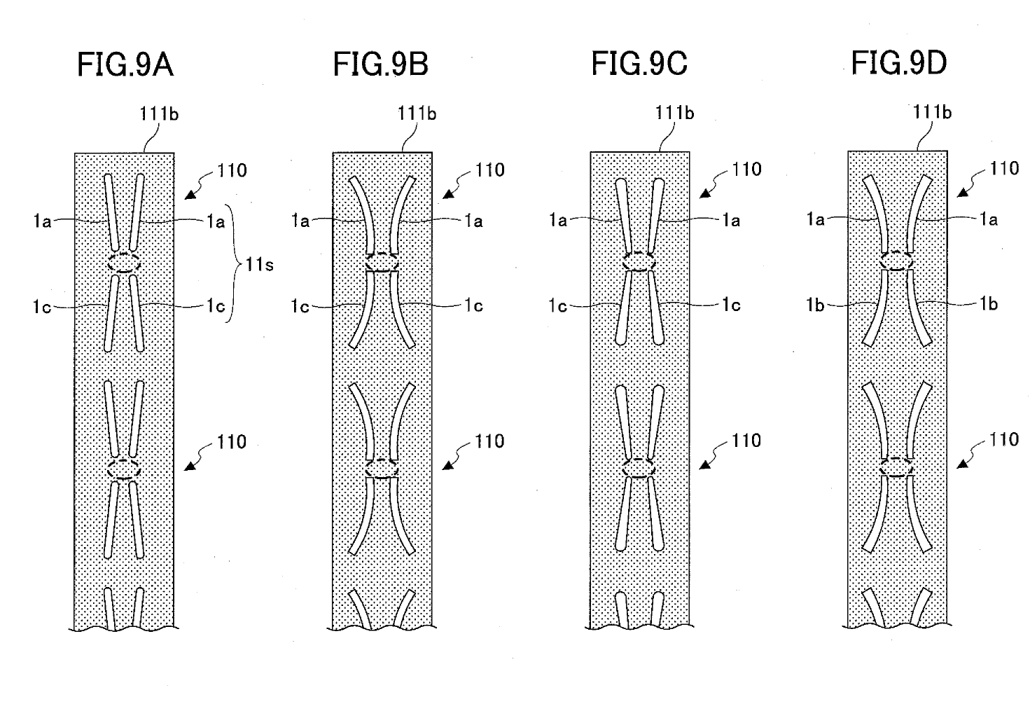

Further, FIG. 9A to FIG. 9D are views showing other examples of the slit assemblies 110 formed at a gas dispersing plate 111b. In these examples as well, the positions corresponding to the opening edges of the gas supply pipes (17a or the like) are shown by dotted lines for explanation.

Specifically, for the gas dispersing plates 111b respectively shown in FIG. 9A to FIG. 9D, the slits corresponding to the second slits 1b of the slit portion his and the slits 11t of the gas dispersing plate 11b shown in FIG. 3B are not included. In this case, the gas flowing out from the gas supply pipes 17a (to 17d) crashes the gas dispersing plate 111h at a region between the two first slits 1a and the two third slits 1c of each of the slit assemblies 110 (hereinafter simply referred to as a center region as well) first, the gas spreads upward, downward, leftward, and rightward, and then flows into the inner tube 11 via the first slits 1a and the third slits 1c. As the slit assembly 110 does not include the slits corresponding to the second slits 1b and the slits 11t, the flow rate of the gas within the inner tube 11 is further decreased.

Further, the first slits 1a and the third slits 1c shown in FIG. 9B are bent toward the longitudinal edges of the gas dispersing plate 111b further from the center region upward or downward. With this structure, the gas that is crashed the center region of the gas dispersing plate 111b is spread toward the entire direction (360°), so that the gas can easily pass through the first slits 1a and the third slits 1c even at regions far from the center region.

Further, the first slits 1a and the third slits 1c shown in FIG. 9C and FIG. 9D are formed such that the width of the first slits 1a and the third slits 1c become larger further from the center region upward or downward. With this structure, the gas can easily pass through the first slits 1a and the third slits 1c even at regions far from the center region.

The design of the slits such as a placement or shapes may be arbitrary determined based on the characteristic of the used gas (molecular weight, concentration, viscosity or the like), so that the distribution and the flow rate of the gas in the inner tube 11 can be controlled.

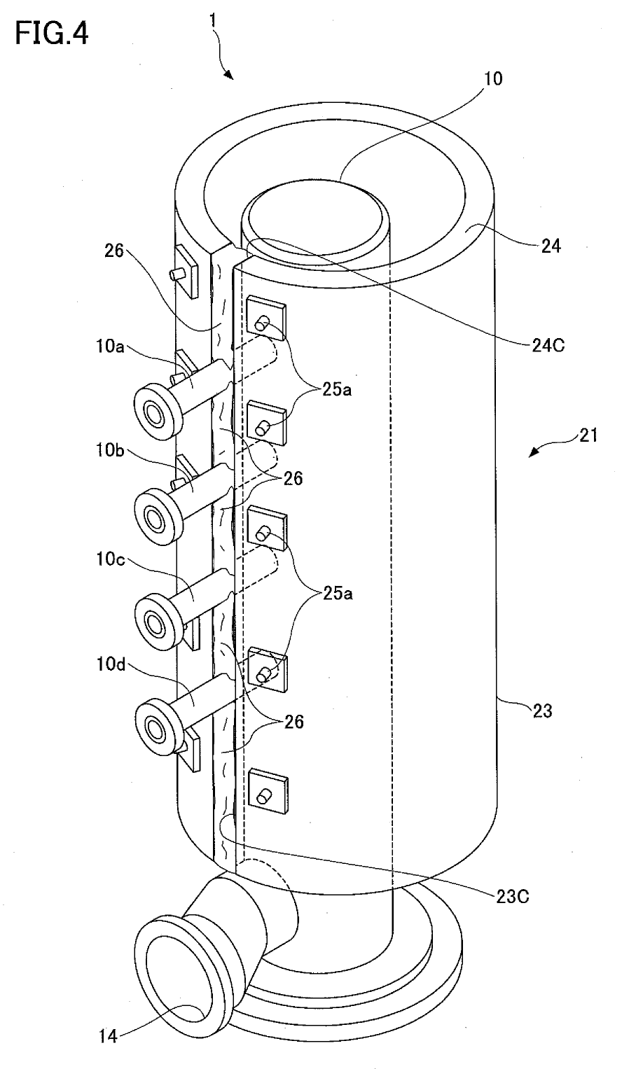

The structure of the heater 20 is explained with reference to FIG. 1 and FIG. 4.

FIG. 4 is a perspective view showing an example of the structures of the first heater 21 of the heater 20 and the outer tube 10 of the embodiment.

The first heater 21 is provided with a slit (23C and 24C) which extends from the upper end toward the lower end of the first heater 21 to receive the guide pipes 10a to 10d of the outer tube 10. Specifically, the slit 23C that extends from the upper end toward the lower end of the tubular body 23 is provided at a part of the tubular body 23 along the longitudinal direction of the tubular body 23. Further, corresponding to the slit 23C, the slit 24C that extends from the upper end toward the lower end of the insulating body 24 is provided at a part of the insulating body 24. Thus, the first heater 21 has a “C” shape when seen in a plan view. Further, the inner surface (except the slit (23C and 24C) of the first heater 21 faces the outer surface of the outer tube 10.

Referring to FIG. 1 and FIG. 4, the outer tube 10 is positioned to be decenterized from the first heater 21 such that the outer surface of the outer tube 10 where the guide pipes 10a to 10d are provided is closer to the inner surface of the first heater 21 than the opposite side. With this, the lengths of the guide pipes 10a to 10d and the gas supply pipes 17a to 17d inside and within the first heater 21 can be shorter. Although the area inside and within the first heater 21 is heated to be a high temperature by the radiant heat from the heater elements 25, the gas supply pipes 17a to 17d in the area can be made shorter in this embodiment. Thus, the process gas in the gas supply pipes 17a to 17d supplied into the inner tube 11 is not heated too high. Therefore, even for the gas whose decomposition temperature is relatively low, the gas does not decompose or activate within the gas supply pipes 17a to 17d before reaching the wafers W.

Further, as shown in FIG. 4, the heat insulator 26 is provided at a space defined by the edges of the slit (23C and 24C) of the first heater 21 and the guide pipes 10a to 10d. The heat insulator 26 may be made of a material having a small thermal conductivity such as silica glass or the like. In this embodiment, the heat insulator 26 may include an outer layer made of a material having a small thermal conductivity such as fiber (glass wool) of silica glass for packaging, and fiber or powder made of silica glass stuffed in the outer layer. With this structure, the heat insulator 26 is formed to have a flexibility to be deformable in accordance with the space to be filled. By using the heat insulator 26, the heat can be prevented from being radiated toward the outside through the space. Thus, it is possible to suppress non-uniformity of the heat in the first heater 21. Further, in order to suppress additional non-uniformity of the heat in the first heater 21, a stick type heater which extends along the slit 24C may be provided at one or both of the edges of the slit 24C of the insulating body 24.

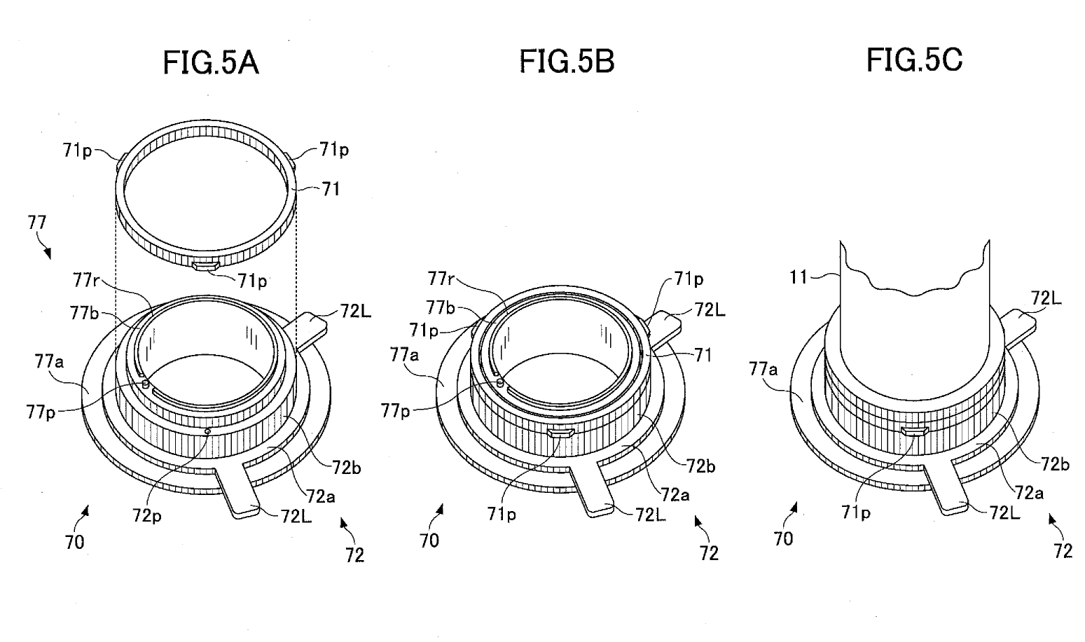

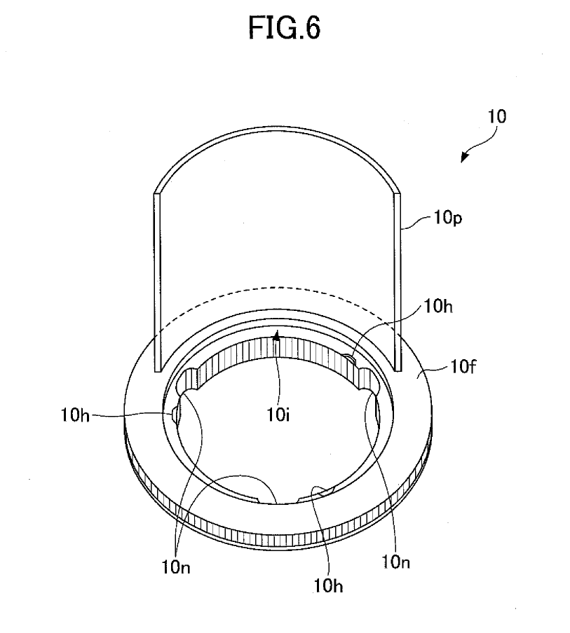

Next, the method of attaching the inner tube 11 to the outer tube 10 is explained with reference to FIG. 5A, FIG. 5B, FIG. 5C and FIG. 6. FIG. 5A, FIG. 5B and FIG. 5C are perspective views of the attaching tool 70 and the fixing ring 71.

Referring to FIG. 5A, the attaching tool 70 includes a base portion 77 and a rotating portion 72 that rotates with respect to the base portion 77. The attaching tool 70 is used for attaching the fixing ring 71 between the outer tube 10 and the inner tube 11.

The base portion 77 includes an annulus plate 77a which is provided with an opening at its center and an annular standing portion 77b which is attached to the annulus plate 77a such that its inner surface matches the inner edge of the annulus plate 77a. As will be explained later, the inner tube 11 is placed on the upper surface of the annular standing portion 77b. Further, the annular standing portion 77b is provided with a ridge portion 77r at the upper surface of the annular standing portion 77b along the inner edges. The outer diameter of the ridge portion 77r is a bit smaller than the inner diameter of the inner tube 11 to determine the position of the inner tube 11. Further, the annular standing portion 77b is provided with a projection 77p at the upper surface of the annular standing portion 77b outside the ridge portion 77r. The projection 77p is provided to correspond and fit to a concave portion (not shown in the drawings) provided at a back surface of the flange 11f of the inner tube 11. The position of the inner tube 11 with respect to the upper surface of the annular standing portion 77b is also determined by fitting the projection 77p to the concave portion of the inner tube 11.

The rotating portion 72 includes a base portion 72a, a cylinder portion 72b, and rotating levers 72L. The base portion 72a is provided with an annular plate. The outer diameter of the base portion 72a is smaller than the outer diameter of the annulus plate 77a of the base portion 77, and the inner diameter of the base portion 72a is a bit larger than the outer diameter of the annular standing portion 77b of the base portion 77. Further, the cylinder portion 72b is attached to the base portion 72a along the inner edge of the base portion 72a. Thus, the inner diameter of the cylinder portion 72b is a bit larger than the outer diameter of the annular standing portion 77b of the base portion 77. Further, the cylinder portion 72b is provided with a projection 72p at the upper surface of the cylinder portion 72b.

The rotating portion 72 is placed on the annulus plate 77a such that the cylinder portion 72b surrounds the annular standing portion 77b of the base portion 77. Further, the two rotating levers 72L are attached to the outer edge of the base portion 72b of the rotating portion 72. By rotating the rotating levers 72L, the rotating portion 72 is rotated with respect to the base portion 77.

The fixing ring 71 has an annulus shape where the inner diameter of which is a bit larger than the outer diameter of the annular standing portion 77b of the base portion 77 and the outer diameter of which is substantially equal to the outer diameter of the cylinder portion 72b of the rotating portion 72. Further, three flange portions 71p are provided at the outer surface of the fixing ring 71 with a substantially even interval.

FIG. 5B shows a status in which the fixing ring 71 is fitted to the rotating portion 72. The fixing ring 71 is placed on the upper surface of the cylinder portion 72b of the rotating portion 72. At this time, the projection 72p formed on the upper surface of the cylinder portion 72b fits a concave portion (not shown in the drawings) formed at the lower surface of the fixing ring 71. With this, the fixing ring 71 is fixed to the rotating portion 72. Further, as the projection 72p is fitted to the concave portion of the fixing ring 71, when the rotating levers 72L of the rotating portion 72 are rotated, the fixing ring 71 is rotated with the rotating portion 72.

FIG. 5C shows a status in which the inner tube 11 is supported by the base portion 77. The inner tube 11 is supported by the base portion 77 such that the back surface of the flange 11f contacts the upper surface of the annular standing portion 77b of the base portion 77. As will be explained later, the back surface of the flange 11f of the inner tube 11 is spaced from the upper surface of the fixing ring 71 at this time. Thus, the fixing ring 71 can be rotated without touching the back surface of the inner tube 11 when rotating the rotating levers 72L of the rotating portion 72.

Subsequently, the shape of the flange 10f of the outer tube 10 is explained with reference to FIG. 6. FIG. 6 is a partial perspective view of the upper portion of the outer tube 10.

For the explanation, only a part of the tube portion 10p of the outer tube 10 is shown for explain the flange 10f. As shown, the tube portion 10p is attached to the upper surface of the flange 10f. The flange 10f is provided with a groove portion 10i at the entire upper portion of the inner surface of the flange 10f. The flange 10f is further provided with three notch portions 10n below the groove portion 10i with a substantially even interval. The notch portions 10n are formed to correspond to the flange portions 71p of the fixing ring 71, which is explained with reference to FIG. 5A. It means that, as will be explained later, when inserting the inner tube 11 supported by the base portion 77 into the outer tube 10, the flange portions 71p of the fixing ring 71 pass the corresponding notch portions 10n of the flange 10f of the outer tube 10.

Further, the flange 10f is further provided with three concave portions 10h with a substantially even interval at the upper surface of the groove portion 10i. The concave portions 10h are also formed to correspond to the flange portions 71p of the fixing ring 71 to fit with the flange portions 71p of the fixing ring 71. As will be explained later, when the rotating levers 72L of the rotating portion 72 are rotated after the flange portions 71p pass the corresponding notch portions 10n, the fixing ring 71 is also rotated such that the flange portions 71p move in the horizontal plane within the groove portion 10i and the flange portions 71p position above the corresponding concave portions 10h. Although an example where the groove portion 10i is provided at the inner surface of the flange 10f is described here, the outer tube 10 may not be provided with the groove portion 10i at the inner surface of the flange 10f and the height of the upper surface of the inner portion of the flange 10f may become substantially equal to that of the outer portion of the flange 10f. In this case, the notch portions 10n may be provided and the concave portions 10h may be provided at the upper surface of the inner portion of the flange 10f.

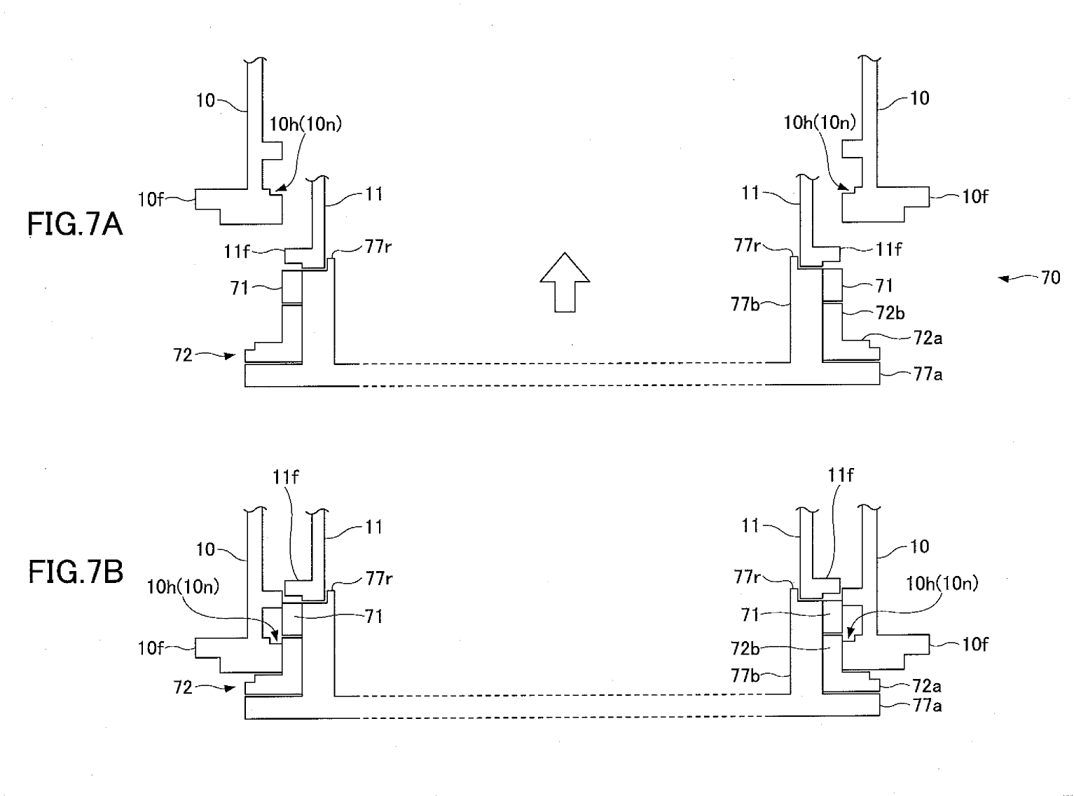

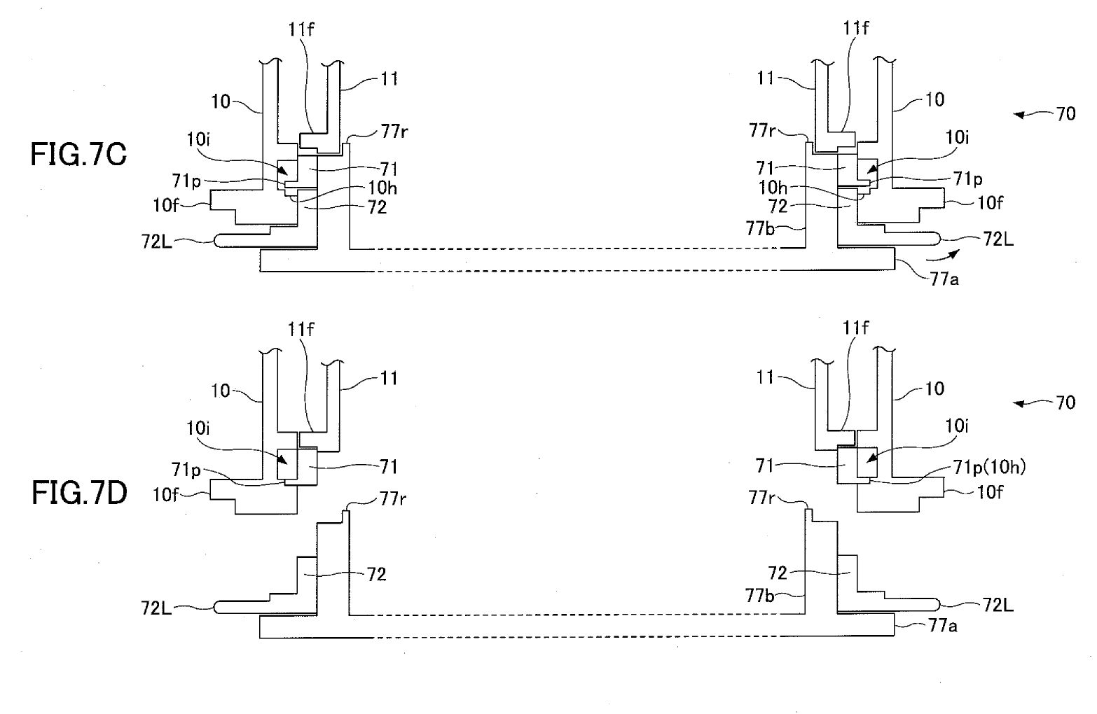

The method of attaching the inner tube 11 to the above described outer tube 10 is further explained with reference to FIG. 7A to FIG. 7D. FIG. 7A to FIG. 7D are cross-sectional views showing the lower parts of the inner tube 11 and the outer tube 10. Although the outer tube 10 is fixed to the base plate 13 via the support plate 12 (see FIG. 1) as described above, the support plate 12 and the base plate 13 are not shown in FIG. 7A to FIG. 7D. Further, in this example, the case where the groove portion 10i is not provided is shown.

FIG. 7A shows a status in which the inner tube 11 is supported by the attaching tool 70. Specifically, the flange 11f of the inner tube 11 is mounted on the annular standing portion 77b of the attaching tool 70. Here, the ridge portion 77r at the upper surface of the annular standing portion 77b engages the inner surface of the flange 11f of the inner tube 11 such that the position of the inner tube 11 with respect to the attaching tool 70 is defined.

By moving the attaching tool 70 and the inner tube 11 supported by the attaching tool 70 upward by the lifting mechanism (not shown in the drawings), the inner tube 11 is inserted into the outer tube 10. Here, for explanation, the concave portions 10h of the flange 10f of the outer tube 10 are shown.

FIG. 7B shows a status in which the base portion 72a of the rotating portion 72 of the attaching tool 70 contacts the lower surface of the flange 10f of the outer tube 10 so that the upward movement is terminated. At this time, the flange portions 71p of the fixing ring 71 which is now placed on the cylinder portion 72b of the rotating portion 72 pass through the corresponding notch portions 10n formed at the inner surface of the flange 10f of the outer tube 10 (not shown in the drawings). Specifically, the lower surface of the flange portion 71p is positioned on the upper surface of the inner portion of the flange 10f.

As shown in FIG. 70, by rotating the rotating levers 72L of the rotating portion 72, the flange portions 71p of the fixing ring 71 are positioned above the corresponding concave portions 10h of the inner portion of the flange 10f of the outer tube 10. Here, the back surface of the flange 11f of the inner tube 11 has a step such that the outer peripheral is concaved than the inner portion. Thus, the upper surface of the fixing ring 71 does not contact the back surface of the flange 11f although the inner tube 11 is supported by the annular standing portion 77b of the attaching tool 70. Therefore, the fixing ring 71 is rotated without contacting the flange 11f. Further, as the inner tube 11 is supported by the upper surface of the annular standing portion 77b of the base portion 77 while being fixed by the projection 77p, the inner tube 11 is not rotated even when the rotating portion 72 is rotated.

Next, as shown in FIG. 7D, when the attaching tool 70 is moved downward by the lifting mechanism (not shown in the drawings), the fixing ring 71 and the inner tube 11 are also moved downward. Thus, the flange portions 71p of the fixing ring 71 are fitted in the concave portions 10h of the outer tube 10, respectively. Therefore, the fixing ring 71 is supported by the flange 10f of the outer tube 10. Further, when the inner tube 11 is moved downward, the flange 10f of the inner tube 11 is placed on the fixing ring 71. In other words, the inner tube 11 which was previously supported by the annular standing portion 77b of the attaching tool 70 is moved to be supported by the fixing ring 71. It means that the inner tube 11 is supported by the flange 10f of the outer tube 10 via the fixing ring 71.

As described above, according to the embodiment, the inner tube 11 is supported by the outer tube 10 via the fixing ring 71. Therefore, the inner tube 11 can be supported by the outer tube 10 without being rotated.

For example, a case where the fixing ring 71 is not used is assumed. In this case, tree flange portions similar to the flange portions 71p of the fixing ring 71 may be provided to the outer surface of the flange 11f of the inner tube 11. With this structure, by fitting these flange portions to the concave portions 10h formed at the upper surface of the groove portion 10i of the flange 10f of the outer tube 10, the inner tube 11 can be fixed to the outer tube 10. However, for this case, it is necessary to rotate the inner tube 11 with respect to the outer tube 10 for aligning the positions of the flange portions and the concave portions 10h, respectively.

However, for the heat treatment apparatus 1 of the embodiment, the inner tube 11 includes the protruding portion 11a where the gas supply pipes 17a to 17d, supported by the guide pipes 10a to 10d of the outer tube 10, are inserted into the gas supply holes H1 to H4 formed at the protruding portion 11a, respectively. Thus, if the inner tube 11 is rotated to be fixed by the outer tube 10, it is difficult to match the positions of the gas supply holes H1 to H4 and the respective gas supply pipes 17a to 17d.

According to the structure of the embodiment, by rotating the fixing ring 71 in order to have the flange portions 71p of the fixing ring 71 fit in the respective concave portions 10h of the outer tube 10, the inner tube 11 is fixed to the outer tube 10 by the fixing ring 71. Thus, the inner tube 11 is only moved upward and downward without being rotated. Therefore, by aligning the position of the inner tube 11 such that the gas supply pipes 17a to 17d are inserted into the respective gas supply holes H1 to H4 of the protruding portion 11a when inserting the inner tube 11 into the outer tube 10, the position of the inner tube 11 with respect to the outer tube 10 is not changed. With this structure, the inner tube 11 can be easily fixed to the outer tube 10.

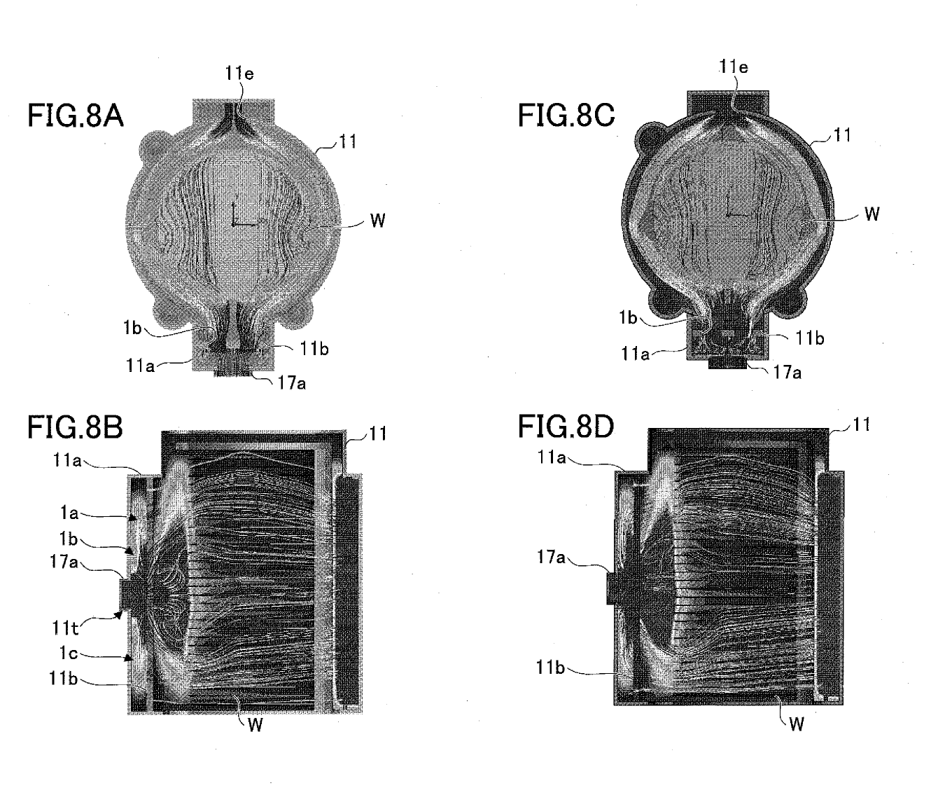

Next, the mechanism of the gas dispersing plate 11b will be explained with reference to FIG. 8A to FIG. 8D. FIG. 8A to FIG. 8D are diagrams showing computer simulation results of a gas supplied to the inner tube 11 from the gas supply pipe 17a through the gas supply hole H1 (see FIG. 2).

FIG. 8A and FIG. 8B show a result in which the gas dispersing plate 11b as shown in FIG. 3B is used, FIG. 8C and FIG. 8D show a result in which the gas dispersing plate 11b is used similar to that shown in FIG. 3B but the slits 11t are not provided. Further, FIG. 8A and FIG. 8C respectively shows a flow pattern of the gas in the inner tube 11 in the horizontal plane at a height of the gas supply pipe 17a. FIG. 8B and FIG. 8D respectively shows a flow pattern of the gas in the inner tube 11 in the vertical direction including the gas supply pipe 17a. The lines shown in FIG. 8A to FIG. 8D are constant velocity lines. Further, in FIG. 8A to FIG. 8D, an exhaust slit 11e formed at the side surface of the inner tube 11 faces the protruding portion 11a. In this embodiment, the gas in the inner tube 11 is exhausted from the exhaust slit 11e to a space between the inner tube 11 and the outer tube 10 to be exhausted from the exhaust pipe 14.

As shown in FIG. 8A and FIG. 8B, the gas supplied from the supply pipe 17a to the protruding portion 11e crashes the gas dispersing plate 11b to spread in the lateral direction and in the vertical direction to be introduced into the inner tube 11 via the slit portions 11s (1a, 1b and 1c) and the slits 11t formed at the gas dispersing plate 11b. As the gas is spread by the gas dispersing plate 11b, the gas flows substantially uniformly in the inner tube 11. Further, as the result of the computer simulation, it is confirmed that the flow rate of the gas discharged from the gas supply pipe 17a to the protruding portion 11a is 90 to 100 m/sec, while the flow rate of the gas above (or between) the wafers W in the inner tube 11 is 30 to 60 m/sec. It means that the gas flows uniformly at a relatively slow speed above the wafers W. Thus, it is possible to perform a uniform heat treatment to the wafers W. Further, as the flow rate of the gas in the inner tube 11 is slow, it is possible to reduce the decrease in temperature of the wafers W by the gas.

Further, the similar result can be obtained based on the result shown in FIG. 8C and FIG. 8D. For the case as shown in FIG. 8A and FIG. 8B, the difference in the flow rate of the gas at the upper part, the middle part, and the lower part in the vertical direction is a bit smaller compared with the case shown in 8C and FIG. 8D. This may be an effect by the slits 11t of the gas dispersing plate 11b as shown in FIG. 38.

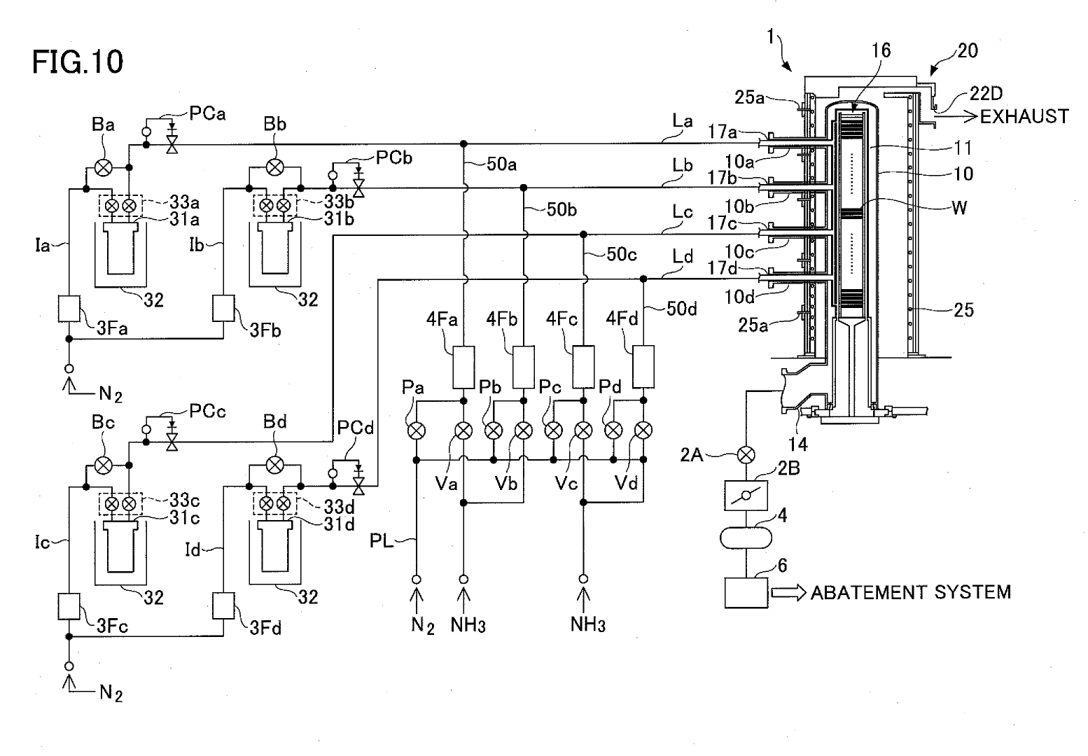

A method of forming gallium nitride (GaN) layers on sapphire substrates (as wafers W) by the heat treatment apparatus 1 of the embodiment is explained with reference to FIG. 10, as an example. FIG. 10 is a view showing an example of a system in which a gas supply system is connected to the heat treatment apparatus 1 of an embodiment.

As shown in FIG. 10, gallium source tanks 31a to 31d are connected to the gas supply pipes 17a to 17d via pipes La to Ld, respectively. The gallium source tanks 31a to 31d are so called “bubblers”. In this embodiment, trimethyl gallium (TMGa) is filled in the source tanks 31a to 31d, respectively. Further, a predetermined carrier gas supply source (high-purity nitrogen gas, for example, just shown as N₂ in FIG. 10) is connected to the gallium source tanks 31a to 31d via pipes Ia to Id on which flow controllers (mass flow controller, for example) 3Fa to 3Fd are provided, respectively. For the carrier gas, high purity nitrogen gas may be used, for example. Pairs of open valves 33a to 33d cooperatively opened and closed are provided between each of the pipes La to Ld and the pipes Ia to Id, near the gallium source tank 31a to 31d, respectively.

Further, bypass pipes on which bypass valves Ba to Bd are provided for connecting the pipes La to Ld and the pipes Ia to Id, respectively are further provided. When the bypass valves Ba to Bd are opened and the open valves 33a to 33d are closed, the carrier gas flows through the bypass pipes to the respective gas supply pipes 17a to 17d to be supplied to the inner tube 11. On the other hand, when the bypass valves Ba to Bd are closed and the valves 33a to 33d are opened, the carrier gas is supplied to the gallium source tanks 31a to 31d to be discharged into the TMGa liquid filled in the gallium source tanks 31a to 31d, respectively. Then, the TMGa steam (or gas) is flowed out from the gallium source tanks 31a to 31d to be supplied to the inner tube 11 via the respective gas supply pipes 17a to 17d.

Further, thermostat baths 32 are provided to the gallium source tanks 31a to 31d, respectively. The thermostat baths 32 are controlled by a temperature controller (not shown in the drawings) to maintain the gallium source tanks 31a to 31d and the TMGa liquid in the gallium source tanks 31a to 31d at a predetermined temperature so that the steam pressure of the TMGa is maintained at a constant value in accordance with the predetermined temperature. While the steam pressure of the TMGa is maintained at a constant value and the pressure in the pipes La to Ld is maintained at a constant value by pressure controllers PCa to PCd provided in the pipes La to Ld, the concentration of the TMGa in the carrier gas flowing through the pipes La to Ld can be maintained at constant, respectively.

Further, pipes 50a to 50d from an ammonia (NH₃) supply source, for example, are connected to the pipes La to Ld, respectively. Flow controllers (mass flow controller, for example) 4Fa to 4Fd and open valves Va to Vd are provided to the pipes 50a to 50d, respectively. When the open valves Va to Vd are opened, NH₃ gas from the NH₃ supply source is introduced into the pipes La to Ld via the pipes 50a to 50d while the flow is controlled by the flow controllers 4Fa to 4Fd, respectively. With this, the mixed gas of TMGa steam (gas), NH₃, and the carrier gas is supplied into the inner tube 11 via the gas supply pipes 17a to 17d.

Further, a purge gas pipe PL which is connected to a purge gas supply source (not shown in the drawings) is provided. In this embodiment, high purity nitrogen gas may be used for the purge gas similar to the carrier gas. The purge gas pipe PL is connected to the pipe 50a at a position between the flow controller 4Fa and the open valve Va via the open valve Pa. Similarly, the purge gas pipe PL is further connected to the pipes 50b to 50d at positions between the flow controllers 4Fb to 4Fc and the open valves Vb to Vd via the open valves Pb to Pd, respectively.

Further, a pump (mechanical for example, mechanical booster pump) 4 and a pump (dry pump, for example) 6 are connected to the exhaust pipe 14 of the outer tube 10 via a main valve 2A and a pressure controller 2B. With this structure, the gas in the outer tube 10 is exhausted while the pressure in the inner tube 11 and the outer tube 10 is maintained at a predetermined pressure. Further, the exhausted gas is led to a predetermined abatement system from the pump 6 and is processed in the abatement system to be exhausted into the air.

With the above structure, according to the following method, the GaN layers are formed on the sapphire substrates, respectively.

First, the substrate support unit 16 is pulled out from the inner tube 11 and downward by the lifting mechanism (not shown in the drawings). Then, plural sapphire substrates having 4 inches diameter, for example, are mounted on the substrate support unit 16 by a wafer loader (not shown in the drawings). Then, the substrate support unit 16 is loaded into the inner tube 11 by the lifting mechanism (not shown in the drawings). At this time, as the support plate 12 is bonded to the lower end of the outer tube 10 via a seal member (not shown in the drawings), the outer tube 10 and the inner tube 11 are sealed.

Then, by the pumps 4 and 6, the outer tube 10 is decompressed to a predetermined layer forming pressure. At this time, the bypass valves Ba to Bd are opened and the open valves 33a to 33d are closed. Then, the flow rate of the nitrogen gas from the carrier gas supply source is controlled by the flow controllers 3Fa to 3Fd. The nitrogen gas whose flow rate is controlled is introduced into the inner tube 11 through the pipes Ia to Id, the bypass valves Ba to Bd, the pipes La to Ld, and the gas supply pipes 17a to 17d, respectively. Further, when the open valves Pa to Pd are opened, the nitrogen gas whose flow rate is controlled by the flow controllers 4Fa to 4Fd is introduced into the inner tube 11 through the pipes 50a to 50d, the pipes La to Ld, and the gas supply pipes 17a to 17d, respectively.

As described above, the sapphire substrates (W) supported by the substrate support unit 16 are heated to a predetermined temperature (850° C. to 1050° C., for example) by flowing the nitrogen gas into the inner tube 11 to purge the inner tube 11 and controlling supply of an electric power to the heater 20 (the first heater 21 and the second heater 22). The temperature of the sapphire substrates is measured by one or more thermo-couple(s) (not shown in the drawings) which is placed in the outer tube 10 along the longitudinal direction of the substrate support unit 16. Then, the electric power supplied to the heater 20 is controlled to maintain the temperature at a constant value, based on the measured temperature.

After purging of the inner tube 11 is completed and the temperature of the sapphire substrates becomes constant at a predetermined temperature, forming of the GaN layers is started. Specifically, the open valves Va to Vd are opened and the valves Pa to Pd are closed so that the NH₃ gas whose flow rate is controlled by the flow controllers 4Fa to 4Fd, respectively, is supplied to the inner tube 11. With this, the atmosphere in the inner tube 11 is altered from a nitrogen atmosphere to an NH₃ atmosphere. Further, the supplied NH₃ gas is decomposed by the heat of the sapphire substrates so that the surfaces of the sapphire substrates are nitrided. After a predetermined period, when the NH₃ concentration in the inner tube 11 becomes constant (substantially equal to the concentration at the NH₃ gas supply source), the open valves 33a to 33d are opened and the bypass valves Ba to Bd are closed. With this operation, the nitrogen gas whose flow rate is controlled by the flow controllers 3Fa to 3Fd is respectively supplied to the gallium source tanks 31a to 31d so that the nitrogen gas including the TMGa steam (gas) is supplied to the inner tube 11 via the pipes La to Ld and the gas supply pipes 17a to 17d, respectively. The TMGa steam (gas) supplied to the inner tube 11 is decomposed by the heat of the sapphire substrates to form Ga atoms to react with N atoms generated by the decomposition of the NH₃ gas. Thus, GaN layers are formed on the sapphire substrates, respectively.

For the embodiment, the gas supply pipes 17a to 17d are provided at the side surface of the inner tube 11, and a process gas (a mixed gas of the carrier gas including the TMGa steam (gas) and the NH₃ gas) is supplied.

Here, for example, if the gas is supplied by a gas supply nozzle extending into the inner tube 11 in the longitudinal direction (vertical direction) of the outer tube 10 from downward to upward, and provided with plural holes, the temperature of the process gas becomes higher as it proceeds toward the upper edge of the gas supply nozzle. Thus, the temperature of the process gas becomes different depending on the position. Therefore, it is difficult to form uniform layers for the plural sapphire substrates. However, according to the embodiment, as described above, the process gas does not flow in the inner tube 11 along the longitudinal direction of the inner tube 11. The process gas is supplied to the sapphire substrates from the gas supply pipes 17a to 17d provided at the side surface of the inner tube 11. Therefore, the process gas is supplied at a substantially equal temperature to the plural sapphire substrates. Thus, uniform layers can be formed for the plural sapphire substrates (wafers W).

Further, according to the embodiment, different from the case where the process gas flows into the inner tube 11 from downward to upward, the process gas is supplied to the sapphire substrates (wafers W) without being decomposed (reacted) by heat. Thus, the process gas can be efficiently used.

Especially, when forming the GaN layers using TMGa and NH₃, if the TMGa gas and the NH₃ gas are supplied by the gas supply nozzle which is extending from downward to upward into the inner tube 11, the TMGa whose decomposition temperature is low is decomposed in the gas supply nozzle or in the inner tube 11. Therefore, Ga is deposited in the gas supply nozzle or in the outer tube 10. If such a deposition occurs, problems such that the forming rate of the GaN layers on the sapphire substrates becomes slower, or the deposited Ga becomes particles which contaminate the apparatus. However, according to the heat treatment apparatus 1 of the embodiment, the TMGa gas and the NH₃ gas can be almost directly supplied to the sapphire substrates from the gas supply pipes 17a to 17d without flowing into the outer tube 10 or into the inner tube 11 for a long time, so that decomposition of TMGa can be suppressed to prevent lowering of the formation of the layers or deposition of Ga.

Further, as shown in FIG. 1 and FIG. 4, the outer tube 10 (and the inner tube 11) is placed to be decenterized from the first heater 21 to shorten the length of the gas supply pipes 17a to 17d within the first heater 21. Therefore, heating of the gas supply pipes 17a to 17d can be suppressed. Thus, decomposition of TMGa caused by heat of the gas supply pipes 17a to 17d can also be suppressed.

The present invention is not limited to the specifically disclosed embodiments, and variations and modifications may be made without departing from the scope of the present invention.

For example, the gas dispersing plate 11b (or 111b, the same in the following) may be made of opaque material. It means that the dispersing plate 11b becomes opaque except for the slit assemblies (11s, 11t). With this structure, radiation of the heat of the wafers W from the slit (23C and 24C) of the first heater 21 through the gas dispersing plate 11b can be reduced. Thus, it is possible to improve the uniform temperature in the inner tube 11. Specifically, the gas dispersing plate 11b may be made of a quartz glass including plural micro bubbles (so called “opaque glass”). Further, the gas dispersing plate 11b may be formed to be opaque by blasting one or both of the surface(s) of a transparent quartz glass by sand blasting or the like, for example. Further, the gas dispersing plate 11b may be formed to be opaque by coating one or both of the surface(s) of a quartz glass by opaque material such as silicon carbide (SiC) or the like, for example.

Further, the gas dispersing plate 11b is not limited to a flat plate, and may be formed to be bent. For example, the gas dispersing plate 11b may be formed to have a curvature substantially similar to that of the side surface of the inner tube 11, or that of the outside edges of the wafers W. Further, the gas dispersing plate 11b may be formed to be integrated with the inner tube 11. The gas dispersing plate 11b may be composed by a part of the side wall of the inner tube 11.

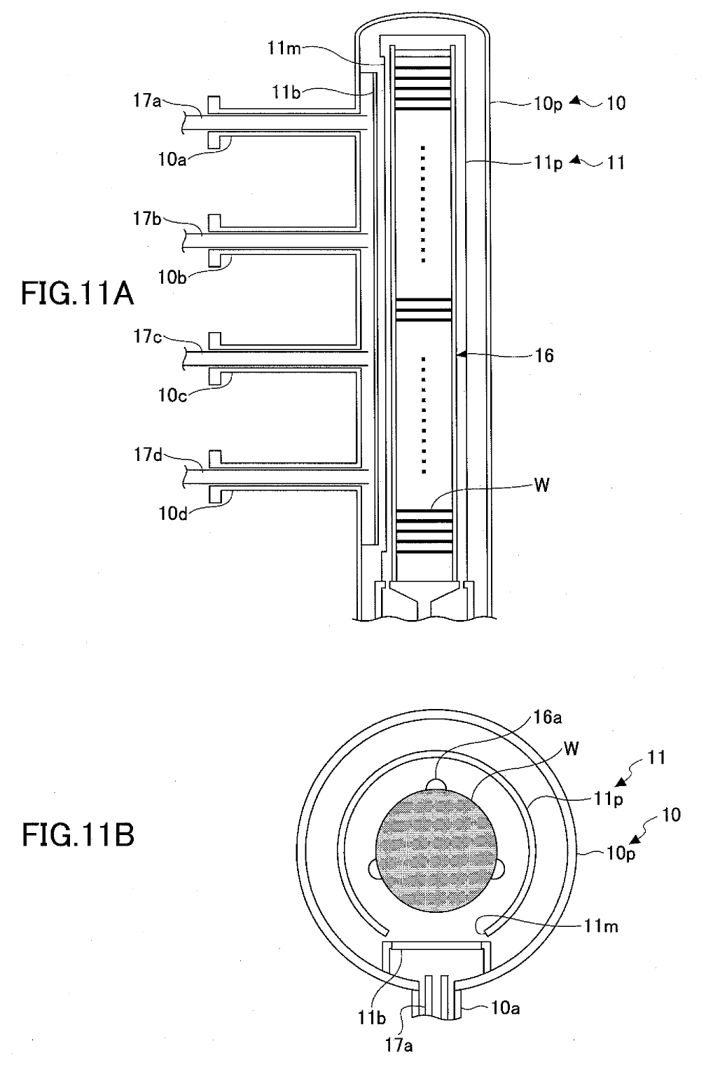

Further, in the above-described embodiment, the gas dispersing plate 11b is placed between the gas supply holes H1 to H4 and the substrate support unit 16 in the inner tube 11. Alternatively, as shown in FIG. 11A and FIG. 11B, the gas dispersing plate 11b may be attached to the inner surface of the outer tube 10. At this time, the inner tube 11 is not provided with the protruding portion 11a, but is provided with an opening 11m corresponding to the gas dispersing plate 11b. Further, for the example shown in FIG. 11A and FIG. 11B, the heat treatment apparatus 1 may not include the inner tube 11. In other words, the substrate support unit 16 may be directly placed in the outer tube 10.

Further, in the above-described embodiment, the four gas supply holes H1 to H4 are provided at the single protruding portion 11a. Alternatively, four protruding portions which are smaller (shorter in the longitudinal direction) than the protruding portion 11a may be provided and gas supply holes corresponding to the gas supply pipes 17a to 17d may be provided to the protruding portions, respectively.

Further, in the above-described embodiment, the protruding portion 11a is formed to have a rectangular box shape, the protruding portion 11a (or plural protruding portions as described above) may be formed to have a bent surface. For example, the protruding portion 11a may be formed to have a hemicycle shape when seen from the top. Further, the protruding portion 11a may be formed to expand from the outside toward the inside as a horn shape.

Further, in the above-described embodiment, the method of forming the GaN layers by the heat treatment apparatus 1 is explained. Layers formed by the treatment apparatus 1 are not limited. For example, the heat treatment apparatus 1 may be used to form silicon nitride layers on silicon wafers by using dichlorosilane (SiH₂cl₂) gas and NH₃ gas as source gases. Alternatively, the heat treatment apparatus 1 may be used to form polycrystalline silicon layers on silicon wafers by using silane (SiH₄) gas as a source gas. Further, the heat treatment apparatus 1 is not limited to forming thin layers, but may be used for performing heat treatment to silicon wafers, for example.

Further, for forming the GaN layers, other organic gallium material such as trialkyl gallium, for example, triethylgallium (TEGa), or gallium chloride (Gacl) may be used instead of TMGa as gallium material.

Further, source tanks which are filled with trialkyl indium such as trimethyl indium (TMIn) may be further provided to correspond to the gallium source tanks 31a to 31d, respectively. In this case, the carrier gas including the TMGa steam (gas) and the carrier gas including the TMIn steam (gas) may be mixed to be supplied to the outer tube 10 (inner tube 11). With this, indium gallium nitride (InGaN) layers are formed.

Further, in order to suppress the decomposition of trialkyl gallium (and/or trialkyl gallium indium) in the gas supply pipes 17a to 17d, the guide pipes 10a to 10d may be formed by double pipes structured by two substantially concentric quartz pipes (in other words, jackets may be further provided to the guide pipes 10a to 10d, respectively). In this case, the carrier gas is flowed in the inner pipe toward the outer tube 10 while a cooling medium, for example, is flowed between the inner pipe and the outer pipe to cool the gas supply pipes 17a to 17d.

Further, in the above-described embodiment, the exhaust pipe 14 is provided at the lower part of the guide pipe 10d. Alternatively, the exhaust pipe 14 may be provided at an opposite side (facing side) of the guide pipes 10a to 10d of the outer tube 10. The exhaust pipe 14 may be provided at the side, the lower portion, or the upper portion of the position opposite to the guide pipes 10a to 10d. Further, when the exhaust pipe 14 is provided at the side of the position opposite to the guide pipes 10a to 10d, two exhaust pipes may be provided at both sides. Further, plural exhaust pipes respectively corresponding to the guide pipes 10a to 10d may be provided at the side the position opposite to the guide pipes 10a to 10d.

Further, the shape of the first heater 21 is not limited. For example, the first heater 21 may be formed to have a polygonal column shape, for example. In this case, the slit (23C and 24C) may be provided to extend along a side of the polygonal column.

Further, a gas supply pipe that extends from downward to upward in the inner tube 11 may be further provided in addition to the gas supply pipes 17a to 17d. In this case, a gas having a lower decomposition temperature may be supplied from the gas supply pipes 17a to 17d while a gas having a higher decomposition temperature may be supplied from the gas supply pipe. With this structure, it is suppressed that the gas having the lower decomposition temperature is decomposed before reaching the wafers W and further, the gas having the higher decomposition temperature can be heated well before reaching the wafers W. It means that the gas can be appropriately heated based on the decomposition temperature.

Further, the gas supply pipes 17a to 17d may be formed by double pipes. In this case, a gas having a lower decomposition temperature may be flowed through the inner pipe while a gas having a higher decomposition temperature may be flowed through the outer pipe. With this structure, the gas having a decomposition temperature can be supplied to the substrates while maintaining the lower temperature.

Further, heaters or cooling jackets may be provided outside the guide pipes 10a to 10d, respectively. With this structure, the temperature of the gas can be easily controlled in accordance with a process condition to improve the efficiency.

The present application is based on Japanese Priority Application No. 2011-92188 filed on Apr. 18, 2011, the entire contents of which are hereby incorporated herein by reference.

What is claimed is:

1. A heat treatment apparatus comprising:
a reaction tube extending in a first direction;
a substrate support unit which is placed in the reaction tube and is configured to be capable of supporting plural substrates along the first direction;
plural gas supply pipes provided at a side surface of the reaction tube to be aligned in the first direction with intervals for supplying a gas into the reaction tube;
a gas dispersing plate which is provided in the reaction tube between opening edges of the plural gas supply pipes and the substrate support unit placed in the reaction tube, the gas dispersing plate being provided with plural opening portions formed to correspond to the gas supply pipes, respectively; and
a heater which is placed outside the reaction tube for heating the substrates.

2. The heat treatment apparatus according to claim 1, further comprising:
an inner tube which is placed inside the reaction tube and outside the substrate support unit, the plural gas supply holes corresponding to the plural gas supply pipes being provided at a side surface of the inner tube,
wherein the gas dispersing plate is provided between the plural gas supply holes and the substrate support unit.

3. The heat treatment apparatus according to claim 2,
Wherein the inner tube is provided with a tube portion and a protruding portion which is formed to protrude from the tube portion, and the plural gas supply holes are formed at the protruding portion.

4. The heat treatment apparatus according to claim 2, further comprising:
a ring member provided between the reaction tube and the inner tube, capable of supporting a lower surface of the inner tube and provided with plural flange portions each of which protrudes from the outer surface of the ring member,
wherein the reaction tube is provided with a concave portion formed at the lower end capable of receiving the plural flange portions of the ring member, and
the inner tube is supported by the reaction tube via the ring member such that the plural flange portions of the ring member are supported in the concave portion.

5. The heat treatment apparatus according to claim 4, further comprising:
the reaction tube is further provided with plural notch portions corresponding to the plural flange portions of the ring member such that the plural flange portions of the ring member are capable of passing through the notch portions when the ring member is moved with respect to the reaction tube in the first direction.

6. The heat treatment apparatus according to claim 1,
wherein the reaction tube is provided with plural guide pipes formed at a side surface of the reaction tube to correspond to the plural gas supply pipes for supporting the plural gas supply pipes, respectively.

7. The heat treatment apparatus according to claim 1,
wherein the gas dispersing plate is attached at an inner surface of the reaction tube.

8. The heat treatment apparatus according to claim 1,
wherein the gas dispersing plate is made of an opaque material.

9. The heat treatment apparatus according to claim 1,
wherein each of the opening portions of the gas dispersing plate includes plural slits.

10. The heat treatment apparatus according to claim 1,
wherein each of the opening portions of the gas dispersing plate includes two slit portions provided to have a space in a second direction perpendicular to the first direction while having a position corresponding to the opening edge of the respective gas supply pipe as a center, and each of the two slit portions is provided to extend in the first direction.

11. The heat treatment apparatus according to claim 10,
wherein the two slit portions of each of the opening portions of the gas dispersing plate are provided such that the further from the center, the greater the distance between the two slit portions in the second direction becomes.

12. The heat treatment apparatus according to claim 10,
wherein the two slit portions of each of the opening portions of the gas dispersing plate are respectively formed to have a width in the second direction smaller than that of the opening edge of the respective gas supply pipe.

13. The heat treatment apparatus according to claim 10,
wherein for each of the opening portions of the gas dispersing plate an opening is not provided at a position corresponding to the opening edge of the respective gas supply pipe.
